(19) United States
(12) Patent Application Publication
(10) Pub. No.: US 2008/0074183 A1
(43) Pub. Date: Mar. 27, 2008

(54) Compensated gain control device

(75) Inventor: Jy-Der David Tai, Phoenix, AZ (US)

Correspondence Address: CHARLES E. BAXLEY, ESQ., 90 JOHN STREET, THIRD FLOOR, NEW YORK, NY, 10038, US

(73) Assignee: Tai-1 Microelectronics Corp.

(21) Appl. No.: 11/528,065

(22) Filed: Sep. 26, 2006

(51) Int. Cl. H03F 3/38

(52) U.S. Cl. 330/10

(57) ABSTRACT

A compensated gain control device includes a comparator having a high and a low voltage input terminal for receiving different voltage inputs, a ramp input terminal for receiving increasing or decreasing ramp signals from a ramp generating device, and an output terminal coupled to a current source of the ramp generating device for actuating the ramp generating device to generate the increasing or decreasing ramp signals alternatively. Another comparator is coupled to the ramp generating device for generating compensating PWM signals, a coupling capacitor is coupled to the output of the other comparator and the load to deliver a constant power to the load by adjusting the duty cycle.

### BACKGROUND OF THE INVENTION

1. Field of the Invention

The present invention relates to a compensated gain control device and more particularly to a compensated gain control device for providing and sustaining or maintaining a constant power gain by adjusting a duty cycle.

2. Description of the Prior Art

In the typical class-D audio power amplifier, audio signals have been provided and used to modulate the carrier waves in order to output the pulse width modulation (PWM) signals which may be employed or used as switching signals. For example, when the input voltage equals one half of the supply voltage, the duty cycle of the PWM signals will be 50%. When the input voltage is smaller than one half of the supply voltage, the duty cycle of the PWM signals will be lower than 50%, on the contrary when the input voltage is greater than one half of the supply voltage, the duty cycle of the PWM signals will be higher than 50%. The high voltage of the PWM signals or the switching signals is the supply voltage, and the low voltage of the PWM signals or the switching signals is the zero voltage. Accordingly, when the PWM signals have a predetermined or constant modulated portion or a predetermined or constant duty cycle, the output power will be decreased when the supply voltage is decreased because the output power is proportional to square of the output voltage.

For the so-called open-loop class-D audio power amplifiers that have been customarily used today, when the PWM signals have a predetermined or constant modulated portion or a predetermined or constant duty cycle, the output power will be decreased when the supply voltage is decreased. In other words the power gain of the audio power amplifiers will be decreased when the supply voltage is decreased. Accordingly, when the class-D audio power amplifiers employs the batteries as the power source, the power gain of the audio power amplifiers will be decreased when the voltage of the batteries is decreased. When the voltage of the batteries is decreased or lowered to a certain degree or to a predetermined value, the batteries will be taken as short of electricity and will be changed with the new ones. At this situation, the residual electricity remained or contained in the batteries will be wasted. In order to properly or completely or fully use the electricity of the batteries and in order to maintain a steady audio output or a steady output volume, the power gain of the audio power amplifiers should be stabilized.

For the typical class-AB audio power amplifiers, a negative feedback method or a so-called close-loop type method has been employed or used in order to prevent the power gain of the audio power amplifiers from being changed regardless the change of the supply voltage and so as to maintain a steady output power. However, when the typical class-D audio power amplifiers employ or use the close-loop type method, the negative feedback circuits will be relatively complicate; this is because the output signals of the typical class-D audio power amplifiers are the PWM switching signals which include high harmonic waves. In addition, in order to fetch only the required audio signals for feedback purposes, the unnecessary high frequency harmonic waves have to be filtered by low-pass filters, such that the manufacturing cost will be increased accordingly, the electric circuit layout will be complicate, and the interference of the high frequency harmonic waves will occur.

The present invention has arisen to mitigate and/or obviate the afore-described disadvantages of the conventional power amplifiers or audio amplifiers.

### SUMMARY OF THE INVENTION

The primary objective of the present invention is to provide a compensated gain control device which employs or uses the open-loop method and the compensating control method in order to avoid or to prevent the supply voltage from affecting the output power.

The other objective of the present invention is to provide a compensated gain control device for providing and sustaining or maintaining a constant power gain by adjusting a duty cycle.

The further objective of the present invention is to provide a compensated gain control device for a class-D audio power amplifier, in which the output power:

P_out=(Vcc×Vcc/R)×[(pulse width/period)−0.5]1

where P_out is the output power of the amplifier,
Vcc is the supply voltage,
R is the output load,
pulse width is the width of the PWM signal,
period is the cycle time of the PWM signal,
duty cycle (or pulse width ratio)=pulse width/period, assuming that the duty cycle is greater than 50%.

If the duty cycle is less than 50% then the power equation becomes

P_out=(Vcc×Vcc/R)×[0.5−(pulse width/period)].

Note that the output power is zero if the duty cycle is 50%. Above equations come from the fact that a blocking capacitor is placed in series with the load. So when the voltage of the input signal is one half of the supply voltage, the duty cycle is 50% and the blocking capacitor will be charged to one half of the supply voltage. When the voltage of the input signal is higher than one half of the supply voltage, the duty cycle will be bigger than 50%. When the voltage of the input signal is lower than one half of the supply voltage, the duty cycle will be smaller than 50%. So when the voltage of the input signal is higher or lower than one half of the supply voltage, the output power will be increased from zero according to the above two equations but the current flows in opposite direction. To simplify the explanation, following discussion assumes that the voltage of the input signal is higher than one half of the supply voltage or when the duty cycle is greater than 50% if otherwise noted.

As defined in equation 1, the output power of the amplifier will be decreased when Vcc is decreased or when the duty cycle is decreased. On the contrary, the output power of the amplifier will be increased when Vcc is increased or when the duty cycle is increased. Because the output power of the class-D power amplifier is decreased when Vcc is decreased, the duty cycle of the PWM signal should be increased to compensate for the loss of the output power and to sustain a constant power of the class-D power amplifier under low supply voltage condition.

In accordance with one aspect of the invention, there is provided a compensated gain control device comprising a first comparator including a high voltage input terminal, a low voltage input terminal, a ramp input terminal, and an output terminal, a voltage divider including a high voltage terminal and a low voltage terminal coupled to the high voltage input terminal and the low voltage input terminal of the first comparator respectively for supplying different voltage inputs to the high voltage input terminal and the low voltage input terminal of the first comparator respectively, a ramp generating device coupled to the ramp input terminal and the output terminal of the first comparator for generating increasing ramp signals and decreasing ramp signals, and a second comparator coupled to the ramp generating device for receiving the increasing ramp signals and the decreasing ramp signals from the ramp generating device and for generating compensated PWM signals, and a coupling capacitor connected between the output of the second comparator and the load.

The first comparator includes a first resistor coupled between the high voltage input terminal and the low voltage input terminal for forming the high voltage input terminal and the low voltage input terminal. The first comparator includes at least one second resistor coupled to the first resistor.

The ramp generating device includes a capacitor coupled to the ramp input terminal of the first comparator, and a current source coupled to the capacitor and coupled to the output terminal of the first comparator. The current source includes a charging device and a discharging device for alternatively coupling to the capacitor and for selectively charging and discharging the capacitor.

The second comparator includes a negative input terminal coupled to the capacitor of the ramp generating device for receiving the increasing ramp signals and the decreasing ramp signals from the ramp generating device. The second comparator includes a positive input terminal arranged to receive an input signal for generating the PWM signals together with the increasing ramp signals and the decreasing ramp signals from the ramp generating circuit.

The coupling capacitor is connected between the output of the second comparator and the load. The other end of the load is connected to ground.

Further objectives and advantages of the present invention will become apparent from a careful reading of the detailed description provided herein below, with appropriate reference to the accompanying drawings.

### BRIEF DESCRIPTION OF THE DRAWINGS

FIG. 1 is an electric circuit illustrating a compensated gain control device which generates the increasing slope of the ramp waveform shown in FIG. 2 for a class-D power amplifier in accordance with the present invention;

FIG. 2 is a diagram illustrating the waveform of the compensated gain control device under the normal supply voltage when input voltage is higher than one half of the supply voltage;

FIG. 3 is an electric circuit similar to FIG. 1, generating the decreasing slope of the ramp waveform shown in FIG.2;

FIG. 4 is a diagram illustrating the changing of the waveforms when the supply voltage is decreased.

### DETAILED DESCRIPTION OF THE PREFERRED EMBODIMENT

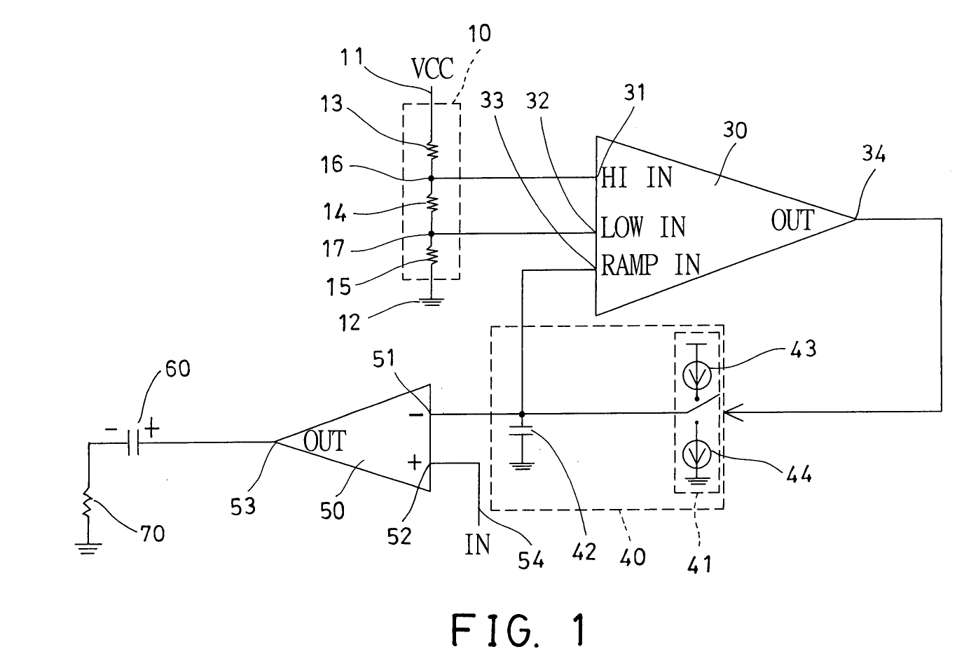

Referring to the drawings, and initially to FIG. 1, a compensated gain control device in accordance with the present invention is illustrated and provided maintaining a constant power gain for such as a class-D power amplifier when the supplied voltage is different or changing. The compensated gain control device comprises a voltage divider 10 coupled to a supply voltage Vcc at one end 11 thereof, and grounded at the other end 12 thereof, and including one or more resistors 13, 14, 15 disposed therein or coupled in series between the supply voltage Vcc 11 and the grounded end 12 for forming or obtaining a high voltage contact or terminal 16 and a low voltage contact or terminal 17.

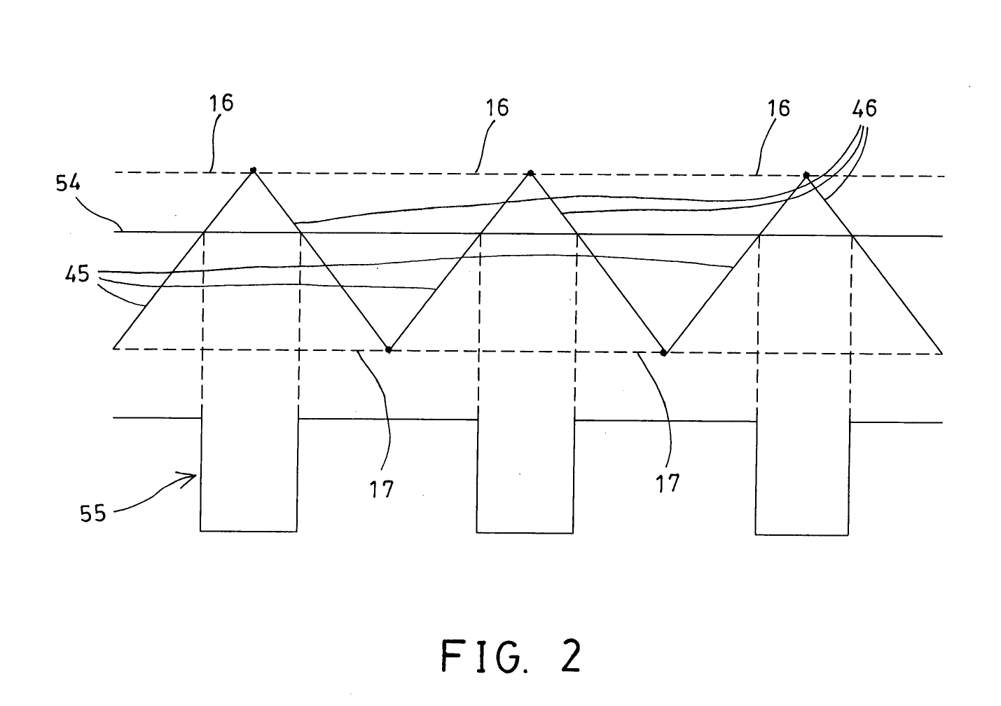

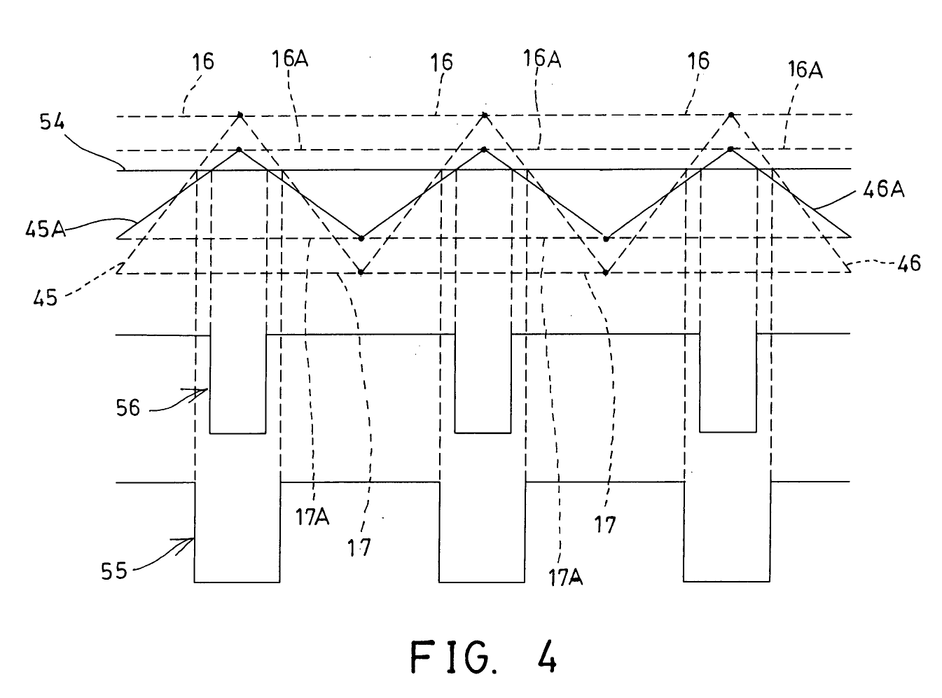

When the supply voltage Vcc is maintained at a certain level, the voltages at the high voltage contact or terminal 16 are greater than that at the low voltage contact or terminal 17 by a certain amount, as indicated and marked as 16 and 17 in FIG. 2 and in FIG. 4. When the supply voltage Vcc is lowered, the voltages at the high voltage contact or terminal 16 and the low voltage contact or terminal 17 will be decreased as indicated and marked as 16A and 17A in FIG. 4. In addition the difference between the voltage 16A and the voltage 17A will be smaller than the difference between the voltage 16 and the voltage 17. Note that the voltages are shown to center at half of the supply voltage.

A first comparator 30 includes a high voltage input terminal 31 and a low voltage input terminal 32 coupled to the high voltage contact or terminal 16 and the low voltage contact or terminal 17 of the voltage divider 10 respectively for receiving the different voltage inputs from the voltage divider 10, and includes a ramp input terminal 33 for coupling to a ramp (signal) generating unit or device 40, and includes an output terminal 34 for coupling to a current source 41 of the ramp generating device 40. The ramp generating device 40 includes a capacitor 42 coupled to the current source 41, and the current source 41 includes a charging device 43 and a discharging device 44 for alternatively or changeably coupling to the capacitor 42 and for selectively charging or discharging the capacitor 42.

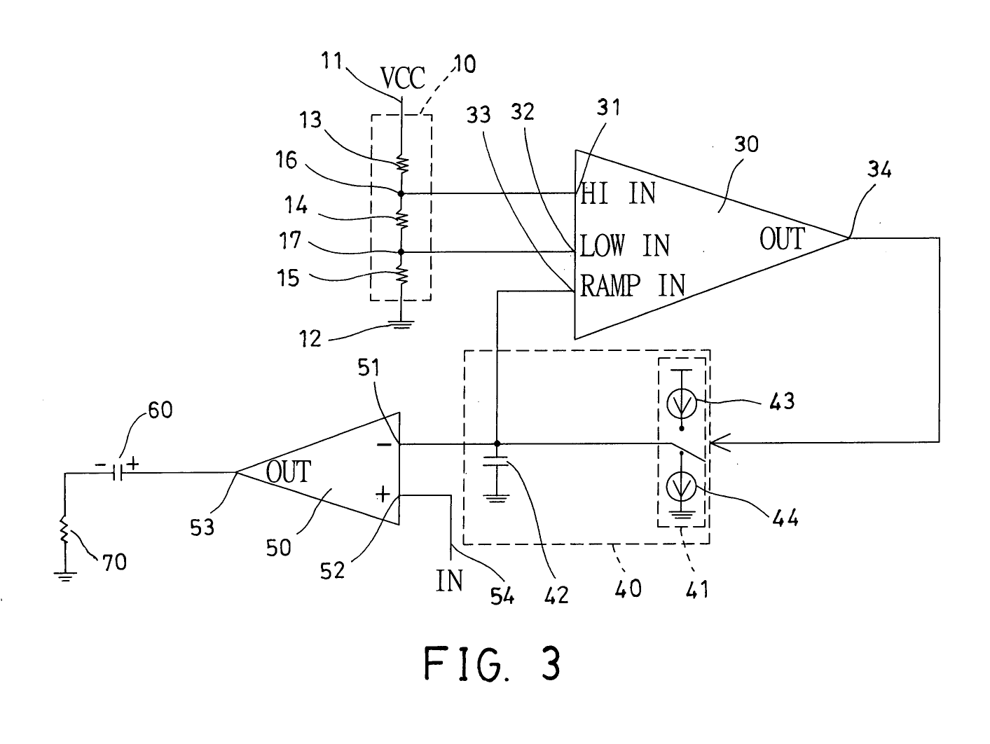

As shown in FIG. 1, when the current source 41 is switched to the charging device 43 or when the charging device 43 is coupled to the capacitor 42, the capacitor 42 may be charged to generate a voltage increasing ramp or signal 45 (FIGS. 2, 4) which will be gradually increased from the lower voltage level at the low voltage contact or terminal 17 to the higher voltage level at the high voltage contact or terminal 16. When the ramp signal 45 that reaches the higher voltage level is supplied into the ramp input terminal 33 of the first comparator 30, the first comparator 30 may then issued an output signal via the output terminal 34 to the current source 41 of the ramp generating device 40, in order to switch the current source 41 to the discharging device 44 (FIG. 3).

When the current source 41 is switched to the discharging device 44 or when the discharging device 44 is coupled to the capacitor 42, the capacitor 42 may be discharged to generate a voltage decreasing ramp or signal 46 (FIGS. 2, 4) which will be gradually decreased from the higher voltage level at the high voltage contact or terminal 16 to the lower voltage level at the low voltage contact or terminal 17. When the ramp signal 46 that reaches the lower voltage level is supplied into the ramp input terminal 33 of the first comparator 30, the first comparator 30 may then issued another output signal via the output terminal 34 to the current source 41 of the ramp generating device 40, in order to switch the current source 41 to the charging device 43 again (FIG. 1), and to generate the voltage increasing ramp or signal 45 again, such that the voltage increasing ramps or signals 45 and the voltage decreasing ramps or signals 46 will be generated alternatively or cyclically.

A second comparator 50 includes a negative input terminal 51, a positive input terminal 52, and an output terminal 53, in which the negative input terminal 51 is coupled to the capacitor 42 of the ramp generating device 40 for receiving the ramps signals 45, 46 from the ramp generating device 40, and the positive input terminal 52 will be coupled or arranged to receive an input signal 54, for allowing the second comparator 50 to generate a PWM output 55 (FIG. 2).

A coupling capacitor 60 is coupled to the output terminal 53 of the second comparator 50. The other end of the coupling capacitor 60 is coupled to a load 70. The load 70 is thus coupled to the coupling capacitor 60. The other end of the load 70 is coupled to ground 12.

In operation, when the input signal at the positive input terminal 52 of the second comparator 50 is higher than the ramp signals at the negative input terminal 51 of the second comparator 50, the output terminal 53 of the second comparator 50 gives a high voltage. On the other hand when the input signal at the positive input terminal 52 of the second comparator 50 is lower than the ramp signals at the negative input terminal 51 of the second comparator 50, the output terminal 53 of the second comparator 50 gives a low voltage. FIG. 2 shows a PWM waveform 55 generated by the circuit in FIG. 1 in which the voltage of the input signal 54 or the voltage at the positive input terminal 52 of the second comparator 50 is higher than half of the supply voltage and the duty cycle of the PWM signal is greater than 50%.

When the input signal 54 is half of the supply voltage, the pulse width of the PWM signal is 50% of the cycle, such that the average output power delivered to the load 70 through coupling capacitor 60 is zero. In other words the average output power is taken from the output of the second comparator 50 through the coupling capacitor 60 such that the DC component of the output signal is blocked by the coupling capacitor 60 and the average value of the PWM signal of 50% duty cycle is zero.

When the input signal 54 is higher than one half of the supply voltage, the pulse width will be increased and the duty cycle of the PWM signal will be greater than 50%, and the average power is indicated to be delivered toward the load 70 through the coupling capacitor 60 in the positive direction. On the contrary when the input signal 54 is lower than one half of the supply voltage, the pulse width will be decreased and the duty cycle of the PWM signal will be smaller than 50%, and the average power is indicated to be delivered toward the load 70 through the coupling capacitor 60 in the opposite direction. FIG. 2 shows an example that when the input signal 54 is higher than one half of the supply voltage, the duty cycle of the PWM signal 55 from the output of the second comparator 50 is greater than 50%.

When the supply voltage Vcc is lowered and when the difference between the voltage levels of the high voltage contact or terminal 16 and the low voltage contact or terminal 17 is decreased and marked as 16A and 17A in FIG. 4, the magnitude of the ramp signal 45, 46 is decreased and marked as 45A and 46A. If the input signal 54 of the second comparator 50 is kept at the same voltage and is higher than one half of the supply voltage then the duty cycle of the PWM signal 55 which had a duty cycle greater than 50% becomes even greater as shown in FIG. 4. If the input signal 54 of the second comparator 50 is lower than one half of the supply voltage then the duty cycle of the PWM signal 55 which had a duty cycle smaller than 50% becomes even smaller. As shown in FIG. 4, the signal 55 which had a duty cycle greater than 50% becomes the signal 56 which has a bigger duty cycle than the signal 55 when the supply voltage is lower or when the magnitude of the ramp signal 45 and 46 is changed to 45A and 46A.

The output power of the amplifier for driving the speaker is calculated by the following equations:

P_out=(Vcc×Vcc/R)×[(pulse width/period)−0.5]

if the duty cycle of the PWM signal is greater than 50%,

and

P_=(Vcc/R)×[0.5 −(pulse width/period)]

if the duty cycle of the PWM signal is less than 50%,

where P₁₃ out is the output power of the amplifier,
Vcc is the supply voltage,
R is the output load,
pulse width is the width of the PWM signal,
period is the cycle time of the PWM signal,
duty cycle (or pulse width ratio)=pulse width/period.

According to the above equations the output power of the amplifier or the PWM signal will be lower if the supply voltage Vcc is smaller. In order to compensate for the power loss due to smaller Vcc the duty cycle should be increased. FIG. 4 shows that the duty cycle of the PWM signal 55 becomes bigger, shown as the signal 56, after Vcc is decreased such that a bigger duty cycle is generated to compensate for the loss of the output power of the PWM signal when Vcc is decreased.

It is to be noted that the cycle time of the ramp signals 45, 46 are shown to be the same before and after Vcc is changed but it is not essential because the output power of the amplifier is irrelevant to the cycle time but to the duty cycle. Preferably when the magnitude of the ramp signal 45, 46 is decreased the slope of the ramp signals 45, 46 should be decreased to maintain the same cycle time or keep the same frequency. To decrease the slope, the charging and discharging current should be made smaller. Since the decrease of the magnitude of ramp 45 and 46 is proportional to the supply voltage Vcc, the charging and discharging current should also be made proportional to the supply voltage Vcc such that the cycle time or PWM frequency can be kept constant.

Briefly, the output power is proportional to the supply voltage and to the pulse width ratio or the duty cycle. When the supply voltage is decreased, the difference between the voltage levels of the high voltage contact or terminal 16 and the low voltage contact or terminal 17 will also be decreased, the second comparator 50 may generate a PWM signal 56 having a greater pulse width ratio for compensating the loss of the output power or for sustaining or maintaining a constant power gain. On the contrary, the difference between the voltage levels of the high voltage contact or terminal 16 and the low voltage contact or terminal 17 will be increased when the supply voltage is increased, the second comparator 50 may generate a PWM signal 55 having a smaller pulse width ratio for compensating the gain of the output power or for sustaining or maintaining a constant power gain. Accordingly, even when the output power of the power supply is decreased, the power gain may be compensated or sustained or maintained at a constant power gain such that the power supply may still be effectively used and is not required to be discarded or wasted.

Accordingly, the compensated gain control device in accordance with the present invention may be used for providing and sustaining or maintaining a constant power gain by adjusting the duty cycle.

Although this invention has been described with a certain degree of particularity, it is to be understood that the present disclosure has been made by way of example only and that numerous changes in the detailed construction and the combination and arrangement of parts may be resorted to without departing from the spirit and scope of the invention as hereinafter claimed.

I claim:

1. A compensated gain control device comprising:
a first comparator including a high voltage input terminal, a low voltage input terminal, a ramp input terminal, and an output terminal,
a voltage divider including a high voltage terminal and a low voltage terminal coupled to said high voltage input terminal and said low voltage input terminal of said first comparator respectively for supplying different voltage inputs to said high voltage input terminal and said low voltage input terminal of said first comparator respectively,
a ramp generating device coupled to said ramp input terminal and said output terminal of said first comparator for generating increasing ramp signals and decreasing ramp signals, and
a second comparator coupled to said ramp generating device for receiving said increasing ramp signals and said decreasing ramp signals from said ramp generating device and for generating compensating pulse signals,
a coupling capacitor coupled to an output of said second comparator, and
a load coupled to said coupling capacitor and ground.

2. The compensated gain control device as claimed in claim 1, wherein said first comparator includes a first resistor coupled between said high voltage input terminal and said low voltage input terminal for forming said high voltage input terminal and said low voltage input terminal.

3. The compensated gain control device as claimed in claim 2, wherein said first comparator includes at least one second resistor coupled to said first resistor.

4. The compensated gain control device as claimed in claim 1, wherein said ramp generating device includes a capacitor coupled to said ramp input terminal of said first comparator, and a current source coupled to said capacitor and coupled to said output terminal of said first comparator.

5. The compensated gain control device as claimed in claim 4, wherein said current source includes a charging device and a discharging device for alternatively coupling to said capacitor and for selectively charging and discharging said capacitor.

6. The compensated gain control device as claimed in claim 4, wherein said second comparator includes a negative input terminal coupled to said capacitor of said ramp generating device for receiving said increasing ramp signals and said decreasing ramp signals from said ramp generating device.

7. The compensated gain control device as claimed in claim 6, wherein said second comparator includes a positive input terminal arranged to receive an input signal for generating said pulse signals together with said increasing ramp signals and said decreasing ramp signals from said ramp generating device.
